(19) United States
(12) Patent Application Publication
(10) Pub. No.: US 2005/0171621 A1
(43) Pub. Date: Aug. 4, 2005

(54) Electronic apparatus and electronic apparatus system

(76) Inventors: Naoki Ura, Tokyo (JP); Satoshi Okada, Tokyo (JP)

Correspondence Address: FISH & RICHARDSON P.C., CITIGROUP CENTER 52ND FLOOR, 153 EAST 53RD STREET, NEW YORK, NY, 10022-4611, US

(21) Appl. No.: 11/038,687

(22) Filed: Jan. 19, 2005

(30) Foreign Application Priority Data
Jan. 20, 2004 (JP) P2004-011693

(51) Int. Cl. G05B 11/01; G06F 3/00; H05K 5/00

(52) U.S. Cl. 700/17; 700/18; 710/1; 361/686

(57) ABSTRACT

An electronic apparatus that reads an HTML file and an applet from a storage portion storing the HTML file and the applet, and transmits the HTML file and the applet to a computer through a communication network, has a data collection portion that collects data from an external process, and a communication portion that transmits the HTML file and the applet read from the storage portion, and the data collected by the data collection portion to the computer through the communication network, wherein the applet involves a CGI applet using CGI, which requests to transmit the data collected by the data collection portion.

### BACKGROUND OF THE INVENTION

1. Field of the Invention

The present invention relates to an electronic apparatus such as a programmable controller which operates and monitors an apparatus disposed in various industrial processes, a production line in a factory, various experimental facilities, or the like, an adjustment apparatus, a data collection apparatus which collects various data, a recorder, and an oscilloscope. The invention also relates to an electronic apparatus system having the electronic apparatus and a computer which is connected to the electronic apparatuses through a communication network to transmit and receive various instructions and data.

2. Description of the Related Art

The following documents relate to an electronic apparatus system configured by various electronic apparatuses and a computer connected to the electronic apparatuses through a communication network to transmit and receive instructions and data.

JP-T-2002-503410 and U.S. Pat. No. 5,805,442 are referred to as related art.

FIG. 6 is a block diagram schematically showing an example of a conventional electronic apparatus system.

Referring to FIG. 6, an electronic apparatus 10 which operates and monitors an apparatus disposed in various industrial processes, a production line in a factory, various experimental facilities, or the like has a control portion 11 having a controlling function, a data collection portion 12 which transmits and receives various data to and from the control portion 11; and a web server 13 which processes input/output data related to the data collection portion 12.

The control portion 11 is a block which is a nucleus portion of the electronic apparatus 10, and which processes, coverts, and treats data supplied from the data collection portion 12. In accordance with the configuration of the control portion 11, the electronic apparatus 10 can function as either of a programmable controller, an adjustment apparatus, a data collection apparatus, a recorder, an oscilloscope, or like apparatuses.

The data collection portion 12 is a software block which obtains historical data from a storage portion 20 described later, and which gives and receives realtime data from and to the control portion 11 in a constant cycle.

The web server 13 is a block having a usual web server function which is popularly used in a server, and obtains data from the data collection portion 12. As described later, the web server is a block including a software program component such as an applet based on JAVA (registered trademark, an object-oriented programming language which is a product of Sun Microsystems, Inc.) which is downloaded to the client side to be implemented.

The electronic apparatus 10 further has the storage portion 20. The storage portion 20 stores an HTML (Hyper Text Markup Language) file 21, and transmits it to the web server 13.

The HTML file 21 is a file defining draw attributes (display components such as trend bars and display positions) of a display on a display device of a client (a computer 30 connected to a network L) described later.

A data portion 22 in the storage portion 20 is data which are collected in a constant cycle from apparatuses disposed in various processes such as an industrial process, a production line, and various experimental facilities.

An applet 23 in the storage portion 20 serves as an application on a web page to be displayed, and is a software having functions of, for example, drawing trend bars and the like, and collecting data.

The communication network L is a public telephone communication line, a LAN (Local Area Network), an Internet communication line, an Intranet communication line, a WAN (Wide Area Network), a wireless communication line, or the like.

The computer 30 is a client computer such as a personal computer which is to be connected to the communication network L, and which has a usual configuration. Namely, the computer is a personal computer (PC) which has a browser 31 and a draw applet 32, and which is placed on the side of the user.

The above electronic apparatus system operates in the following manner.

When monitoring of the process is to be started, the user first transmits an HTML download request from the browser 31 of the computer 30 to the web server 13 in the electronic apparatus 10 through the communication network L (A).

As a result, the web server 13 extracts the HTML file 21 which is stored in the storage portion 20 and which defines draw attributes, and transmits the file to the computer 30 through the communication network L (A).

Then, the web server 13 reads the applet 23 which is an application on a web page, from the storage portion 20, and transmits the applet to the browser 31 (B). The transmitted applet 23 operates as the draw applet 32 on the computer 30.

The draw applet 32 receives data of the process from the data collection portion 12 functioning on the electronic apparatus 10, with using a dedicated socket (port) different from a socket (port) through which the HTML file 21 and the applet 23 are downloaded. The draw applet 32 receives the data of the process at a timing different from that when the applet 23 is downloaded (C).

As a result of this function, with using usual browser software (the browser 31), the user of the computer 30 can monitor various data of the process processed by the electronic apparatus 10, i.e., data processed in a process such as an industrial process, a production line, and various experimental facilities, on the computer 30 in a display form of a web page through the communication network L.

Although the example in which only one electronic apparatus 10 is connected to the communication network L is shown in FIG. 6, a plurality of such electronic apparatuses may be connected to the network.

However, the above electronic apparatus system has the following problem.

In order to collect data, the draw applet 32 of the computer 30 must use the dedicated socket (port: TCP/IP, the port indicated by the arrow (C) in FIG. 6) different from the socket (port indicated by the arrows (A) and (B) in FIG. 6) through which the HTML file 21 and the applet 23 of the electronic apparatus 10 are transmitted.

In the case where such communication is to be carried out on the communication network L such as the Internet, special setting for realizing communication must be performed in a firewall of the communication network L to which the electronic apparatus 10 and the computer 30 belong. Therefore, even when the computer 30 is coupled to the communication network L, the system cannot access the electronic apparatus 10 unless such special setting is performed.

### SUMMARY OF THE INVENTION

The object of the invention is to enable a computer to access an electronic apparatus from anywhere without requiring special setting as far as the computer is connected to a communication network, whereby the status of a process can be easily known and the whole system can be efficiently operated.

The invention provides an electronic apparatus that reads an HTML file and an applet from a storage portion storing the HTML file and the applet, and transmits the HTML file and the applet to a computer through a communication network, having: a data collection portion that collects data from an external process; and a communication portion that transmits the HTML file and the applet read from the storage portion, and the data collected by the data collection portion to the computer through the communication network, wherein the applet involves a CGI applet using CGI, which requests to transmit the data collected by the data collection portion.

Furthermore, the communication portion transmits the HTML file, the applet and the data to the computer with using an identical port.

Furthermore, the communication portion has a CGI communication portion that obtains data from the data collection portion in response to a request from the CGI applet.

The invention also provides an electronic apparatus system having an electronic apparatus and a computer which are connected through a communication network, wherein the electronic apparatus involves: a data collection portion that collects data from an external process; and a communication portion that transmits an applet read from a first storage portion storing an HTML file and the applet, and the data collected by the data collection portion to the computer, the applet involves a CGI applet using CGI, which requests to transmit the data collected by the data collection portion, and the computer comprises a second storage portion storing the HTML file stored in the first storage portion, and reads the HTML file from the second storage portion.

Furthermore, the computer performs a backup process in order to write the HTML file stored in the first storage portion into the second storage portion.

Furthermore, the communication portion transmits the applet and the data to the computer with using an identical port.

Furthermore, the first storage portion stores a communication proxy in order to communicate between the computer and the electronic apparatus, the second storage portion stores the applet stored in the first storage portion and the communication proxy, and the computer reads the HTML file, the applet and the communication proxy from the second storage portion.

Furthermore, the computer performs a backup process in order to write the HTML file, the applet and the communication proxy stored in the first storage portion into the second storage portion.

According to the electronic apparatus, Display instructions for an HTML file related to drawing and actual process data can be separately transmitted through the same HTTP port with CGI. Therefore, it is not necessary to use a different dedicated socket (port: TCP/IP), and special setting for realizing communication is not required in a firewall of the network to which the electronic apparatus 10 and the computer 30 belong.

According to the electronic apparatus system, an HTML file 25 related to drawing is previously transmitted by the backup process. The file is set as display instructions in the computer, and thereafter an applet and various data are transmitted with CGI. Therefore, display instructions and data can be transmitted through the HTTP port at different timings. The processing speed becomes higher. Further, it is not necessary to use a different dedicated socket (port: TCP/IP), and special setting for realizing communication is not required in a firewall of the network to which the electronic apparatus 10 and the computer 30 belong.

According to the electronic apparatus system, display instructions for the HTML file 25 related to drawing, the applet related to displaying, and a communication proxy are transmitted with CGI. Thereafter, only various data are transmitted. Consequently, high-speed processing is realized, and display instructions and data can be transmitted through the HTTP port at different timings. Therefore, it is not necessary to use a different dedicated socket (port: TCP/IP). Moreover, special setting for realizing communication is not required in a firewall of the network to which the electronic apparatus 10 and the computer 30 belong.

### BRIEF DESCRIPTION OF THE DRAWINGS

FIG. 1 is a block diagram showing the configuration of a first embodiment of the invention;

FIG. 2 is a flowchart showing the operation of the first embodiment of the invention;

FIG. 3 is a block diagram showing the configuration of a second embodiment of the invention;

FIG. 4 is a block diagram showing the configuration of a third embodiment of the invention;

FIG. 5 is a flowchart showing the operation of the third embodiment of the invention; and

FIG. 6 is a block diagram showing the configuration of a conventional electronic apparatus system.

### DETAILED DESCRIPTION OF THE PREFERRED EMBODIMENTS

Embodiments of the invention will be described in detail with reference to the drawings.

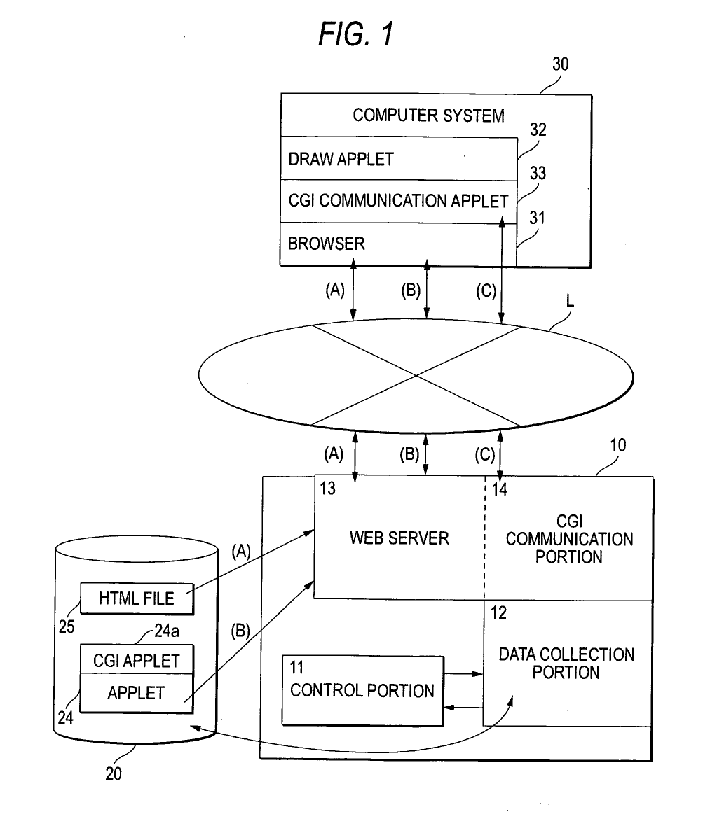

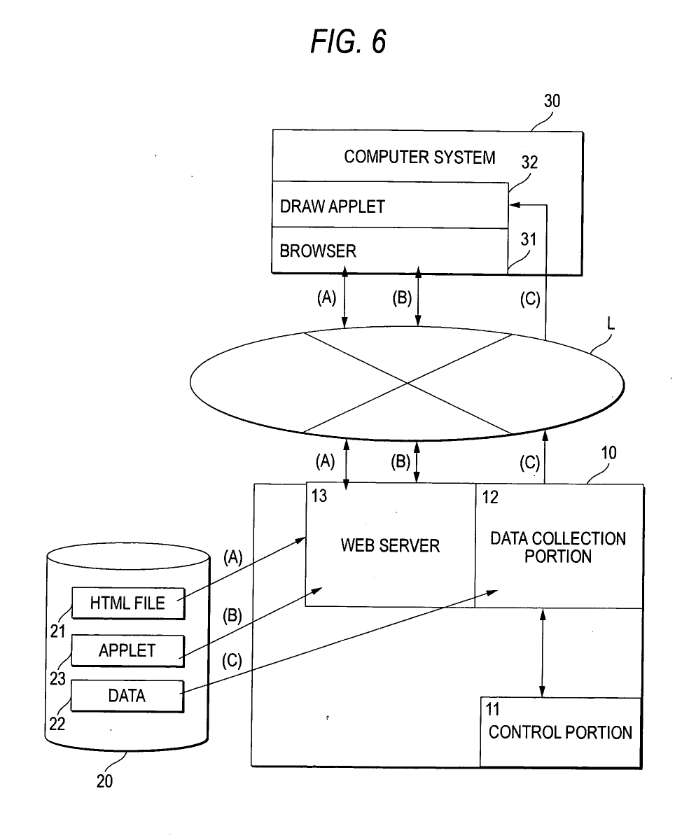

FIG. 1 is a block diagram showing the configuration of a first embodiment of the invention. In FIG. 1, the components denoted by the same reference numerals of those in the conventional example shown in FIG. 6 have the same function, and therefore their description will be omitted.

The system according to the invention employs the CGI (Common Gateway Interface) standard.

The CGI standard is a standard interface for using an external program from a web server (HTML file), and has a system which can transmit a result of the process as a reply to a browser on a computer of a client. Therefore, it is possible to produce a dynamic web page which cannot be described by the HTML file alone. The web server, and the external program which is activated by the CGI standard exchange data through an HTTP (Hyper Text Transfer Protocol) port which is used in usual input/output operations.

Namely, as shown in FIG. 1, a CGI communication portion 14 is added to the data collection portion 12 in the electronic apparatus 10, and a CGI applet 24a is added into an applet 24 stored in the storage portion 20.

The contents stored in the CGI applet 24a are downloaded to the computer 30 to operate as a CGI communication applet 33.

An HTML file 25 in the storage portion 20 has also a function of defining data to be collected.

The electronic apparatus 10 shown in FIG. 1 performs the data collecting operation in the same manner as the conventional one shown in FIG. 6. Namely, the data collection portion 12 obtains historical data from the storage portion 20, and gives and receives realtime data from and to the control portion 11 in a constant cycle.

In this above configuration, in response to an operation on the browser 31 in the computer 30, an HTML download request is issued to the web server 13 through the communication network L, and the HTML file 25 in the storage portion 20 is then read to be downloaded from the web server 13 to the side of the computer 30 (A).

Then, a necessary applet 24 is read from the storage portion 20 in the same manner, and downloaded from the web server 13 to the side of the computer 30 (B).

The applet 24 includes the CGI applet 24a. When the applet is downloaded to the computer 30, the CGI applet 24a functions as the CGI communication applet 33 to acquire data from the CGI communication portion 14 in the electronic apparatus 10, through the communication network L (C).

The CGI communication applet 33 uses the HTTP port (C) to communicate with the CGI communication portion 14 through the web server 13. Then, the CGI communication portion 14 acquires various data from the data collection portion 12, and transmits the data to the browser 31 of the computer 30 with using the HTTP port (C).

As a result of this operation, the display instructions and data are transmitted at different timings to the browser 31 without special setting, by CGI communication between the computer 30 and the electronic apparatus 10.

In accordance with the transmitted display instructions and data, thereafter, the browser 31 displays the statuses of various target processes, in the form of a web page on a display device of the computer 30.

In this way, with using usual browser software (browser 31), the user of the computer 30 can monitor various data in a process which is processed by the electronic apparatus 10, such as an industrial process, a production line, and various experimental facilities, through the communication network L and in the display form of a web page.

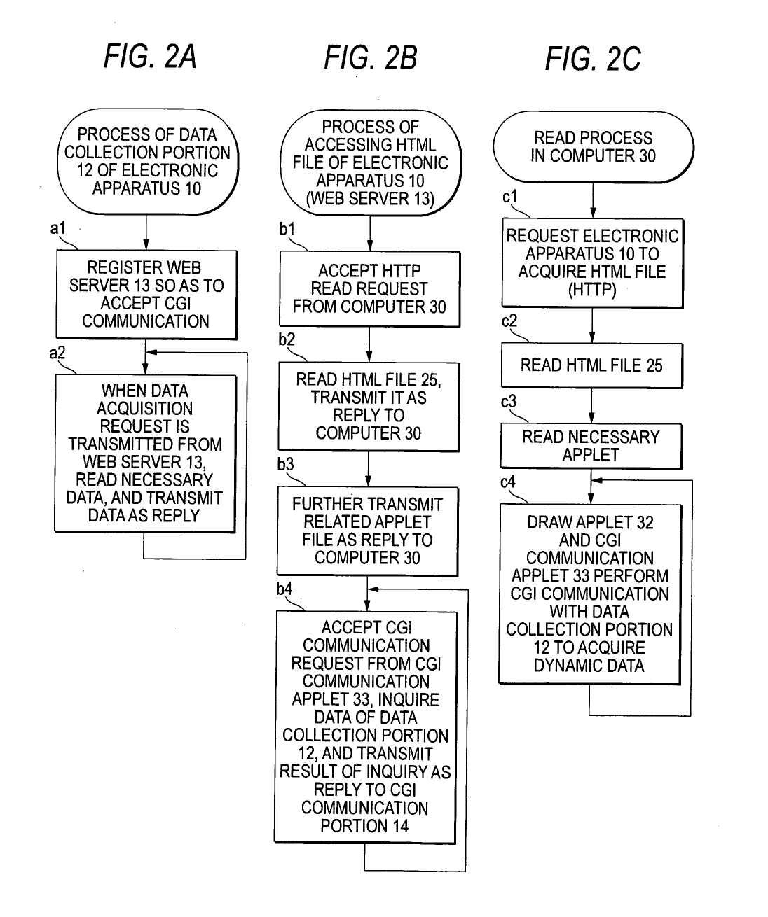

Next, the operation of the electronic apparatus system of the invention will be described in detail with reference to the flowchart of FIG. 2.

FIG. 2A shows a communication process of the data collection portion 12 of the electronic apparatus 10, FIG. 2B shows an HTML file access and communication process of the web server 13 of the electronic apparatus 10, and FIG. 2C shows a process in which the computer 30 communicates with the electronic apparatus 10.

In step a1 of FIG. 2A, the data collection portion 12 of the electronic apparatus 10 registers the CGI communication portion 14 in the web server 13 so as to accept CGI communication.

In step a2 of FIG. 2A, the process waits for transmission of a data acquisition request from the web server 13. When the transmission is received, the process reads data corresponding to the request, and transmits the data to the web server 13 as a reply.

In step b1 of FIG. 2B, the web server 13 accepts an HTTP read request from the computer 30.

In step b2 of FIG. 2B, the HTML file 25 is read from the storage portion 20, and then sent as a reply to the side of the computer 30.

In step b3 of FIG. 2B, a related applet 24 is read from the storage portion 20, and then sent as a reply to the side of the computer 30.

In step b4 of FIG. 2B, if a CGI communication request is issued from the side of the computer 30, the request is accepted, data are acquired from the data collection portion 12, and a result of the acquisition is sent to the computer 30.

In step c1 of FIG. 2C, the computer 30 requests the electronic apparatus 10 through the browser 31 to acquire an HTML file through the HTTP port.

In step c2 of FIG. 2C, the computer 30 reads the transmitted HTML file 25 to obtain the file as the draw applet 32.

In step c3 of FIG. 2C, the computer reads an applet 24 which is subsequently transmitted, and which is related to the HTML file 25, and sets the CGI communication applet 33 or the like.

In step c4 of FIG. 2C, the draw applet 32 accesses the web server 13 in the electronic apparatus 10, by CGI communication through the CGI communication applet 33 to acquire data of the process.

In this way, the computer 30 can obtain the HTML file 25 which functions as the base of drawing, and the applet 24 and the CGI applet 24a which are related to the file, from the electronic apparatus 10 by operating the browser 31, and then obtain data of the process by CGI communication.

Therefore, display instructions for an HTML file related to drawing, and actual process data can be separately transmitted through the same HTTP port. Further, the actual process data is transmitted to the computer 30 in response to the CGI communication applet 33 which uses the CGI. Therefore, it is not necessary to use a different dedicated socket (port: TCP/IP), and special setting for realizing communication is not required in a firewall of the network to which the electronic apparatus 10 and the computer 30 belong.

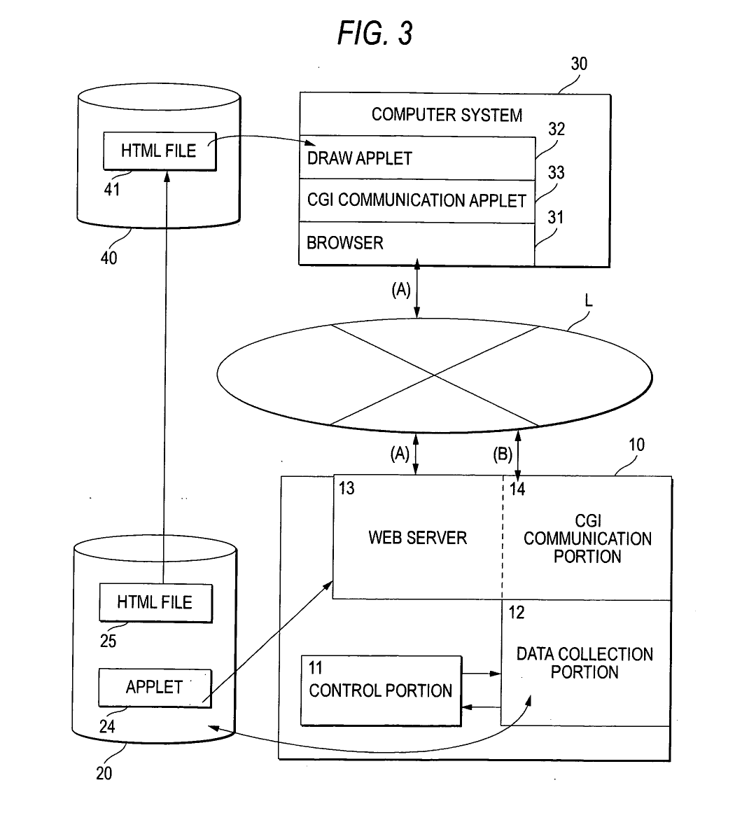

In the first embodiment shown in FIG. 1, the HTML file 25 and the applet 24 are in the storage portion 20 on the side of the electronic apparatus 10. In the case where the communication network L between the computer 30 and the electronic apparatus 10 has a narrow band width, therefore, it may take long time before various files and data arrive from the side of the electronic apparatus 10 to the side of the computer 30, and a display is implemented. A second embodiment shown in FIG. 3 is configured so as to shorten the time.

In the second embodiment shown in FIG. 3, a backup tool in the computer 30 is previously used and a necessary HTML file 25 is transmitted to a storage portion 40 of the computer 30 to be stored therein.

Specifically, the computer 30 uses the backup tool which operates in a backup process during a startup time, to previously transmit the HTML file 25 in the storage portion 20 of the electronic apparatus 10, as an HTML file 41 to the storage portion 40 of the computer 30 serving as a client. The transmitted HTML file is stored as the draw applet 32. The HTML file 41 defines the kind of date to be collected.

Thereafter, the user operates the browser 31 to cause the communication applet and the applet 24 of the CGI applet 24a in the storage portion 20 to be downloaded to the computer 30 (A).

The subsequent processes are identical with those in the first embodiment shown in FIG. 1. Specifically, the processes of steps b1, b2 in the flowchart of FIG. 2 are previously carried out in the backup process, and the other subsequent processes are performed in the same flow.

As a result, only the CGI communication applet 33 is downloaded to the computer 30 in which the draw applet 32 already exists (B). When only necessary data are collected from the web server 13, therefore, various data can be monitored in the display form of a web page.

Specifically, the CGI communication applet 33 uses the HTTP port (B) to communicate with the CGI communication portion 14 through the web server 13. Then, the CGI communication portion 14 acquires various data from the data collection portion 12, and transmits the data to the browser 31 of the computer 30 through a communication line connected to the HTTP port (C).

As a result of this operation, the display instructions and data are transmitted at different timings to the browser 31 without special setting, by CGI communication between the computer 30 and the electronic apparatus 10.

In accordance with the transmitted display instructions and data, thereafter, the browser 31 displays the statuses of various target processes, in the form of a web page on the display device of the computer 30.

In this way, with using usual browser software (browser 31), the user of the computer 30 can monitor various data in a process which is processed by the electronic apparatus 10, such as an industrial process, a production line, and various experimental facilities, through the communication network L and in the display form of a web page.

In the second embodiment, the computer 30 previously obtains the HTML file 25 which functions as the base of drawing, from the electronic apparatus 10 in the backup process. In response to a subsequent operation on the browser 31, the computer obtains the applet 24 including the CGI communication applet 33, and then obtains data of the processes by CGI communication.

Consequently, the HTML file 25 related to drawing is previously transmitted by CGI communication in the backup process to be set as display instructions in the computer, and thereafter an applet and various data are transmitted with using the CGI. Therefore, display instructions and data can be transmitted through the HTTP port at different timings. The processing speed is higher than that in the first embodiment. Therefore, it is not necessary to use a different dedicated socket (port: TCP/IP), and special setting for realizing communication is not required in a firewall of the network to which the electronic apparatus 10 and the computer 30 belong.

Alternatively, the second embodiment may be configured so that not only the HTML file 25 in the storage portion 20, but also the applet 24 may be previously transmitted to and stored into the computer 30 serving as a client.

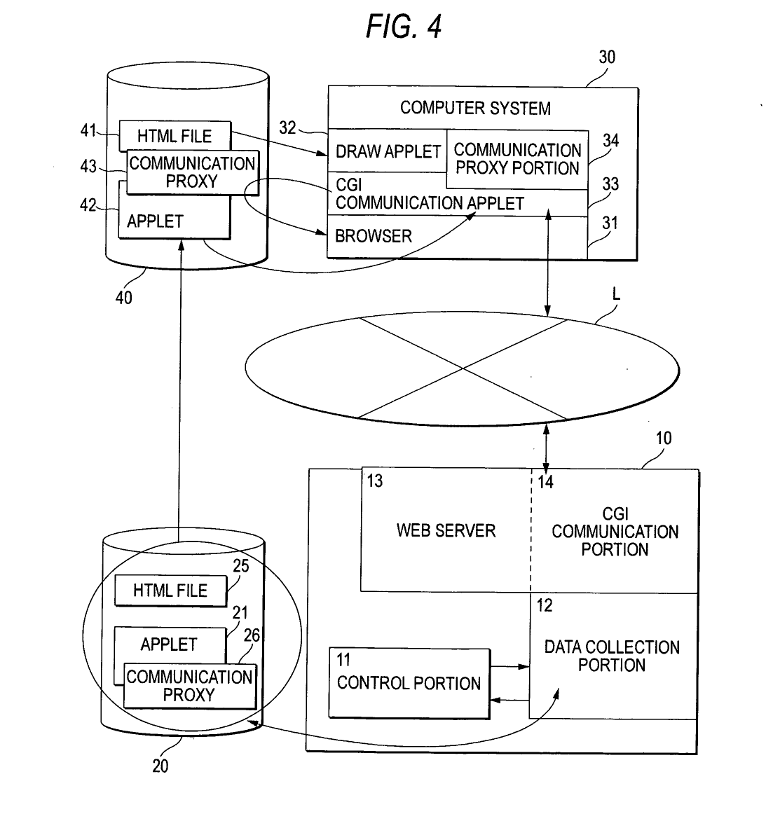

An example of such a configuration is shown as a third embodiment in FIG. 4.

The applet 24 is restricted to perform only communication with the electronic apparatus 10 from which the applet itself has been downloaded. Therefore, in the third embodiment shown in FIG. 4, a communication proxy 26 for enabling communication between the electronic apparatus 10 and the computer 30 through the communication network L is previously stored in the storage portion 20 on the side of the electronic apparatus 10.

In the backup process on the side of the computer 30, the communication proxy program in the communication proxy portion 26 is transmitted together with the HTML file 25 and the applet 21 in the same storage portion 20 to the storage portion 40 of the computer 30, and then loaded to the computer 30 as a communication proxy portion 34.

Namely, in the backup process, the computer 30 obtains the HTML file 25 and the applet 21 in the storage portion 20 disposed in the electronic apparatus 10 to store those into the storage portion 40 in the computer 30 as the HTML file 41 and an applet 42.

In the backup process, the computer 30 also obtains the communication proxy 26 in the storage portion 20 to store it into the storage portion 40 as a communication proxy 43.

Then, the computer 30 sets the contents of the HTML file 25 and the applet 24 in the storage portion 40 as the draw applet 32 and the CGI communication applet 33, respectively, and, in order to make the communication flexible, further sets the contents of the communication proxy 43 as a communication proxy portion 34.

According to the configuration, CGI communication which is similar to that in the above-described first or second embodiment can be realized through the communication proxy portion 34.

In the third embodiment also, in response to an operation on the browser 31, the computer 30 obtains the HTML file 25 which functions as the base of drawing, and the applet 24 which is related to the file, and which includes the CGI communication applet (including also the communication proxy 26), from the electronic apparatus 10, and then obtain data of the process by CGI communication.

Therefore, display instructions for the HTML file 25 related to drawing, and actual process data can be separately transmitted through the same HTTP port by CGI communication. Unlike the prior art, it is not necessary to use a different dedicated socket (port: TCP/IP), and special setting for realizing communication is not required in a firewall of the network to which the electronic apparatus 10 and the computer 30 belong.

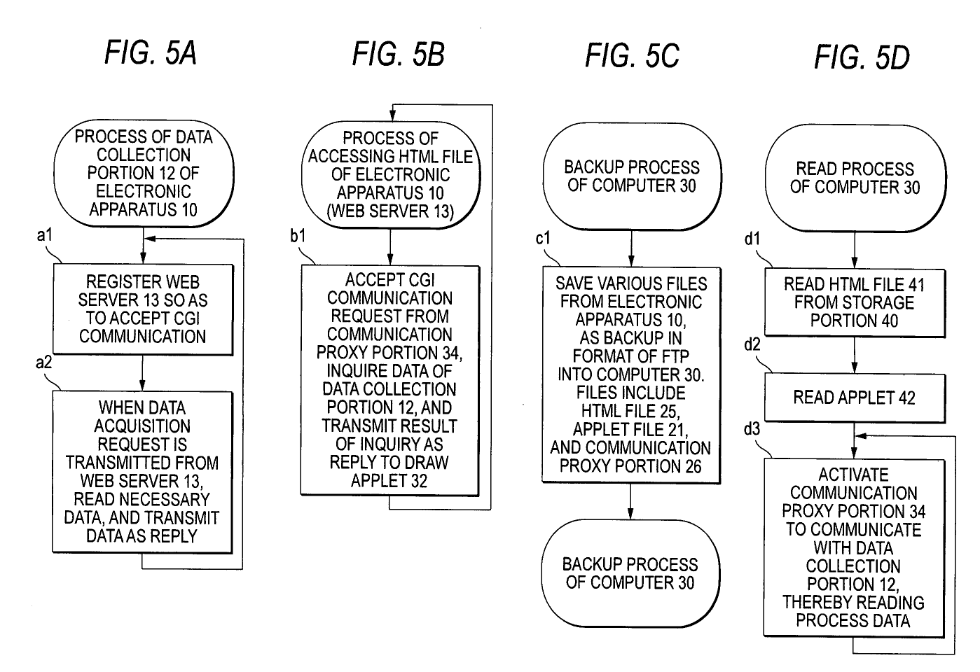

The operation of the third embodiment will be described in detail with reference to the flowchart of FIG. 5.

FIG. 5A shows a communication process of the data collection portion 12 of the electronic apparatus 10, FIG. 5B shows the communication process of the web server 13 of the electronic apparatus 10, FIG. 5C shows the backup process of the computer 30, and FIG. 5D shows a process in which the computer 30 communicates with the electronic apparatus 10.

In step a1 of FIG. 5A, the data collection portion 12 of the electronic apparatus 10 registers the web server 13 so as to accept CGI communication.

In step a2 of FIG. 5A, after the process of step a1, the process waits for transmission of a data acquisition request by the computer 30, from the web server 13. When the data acquisition request is accepted, the process reads data corresponding to the request, and transmits the data to the web server 13.

In step b1 of FIG. 5B, the web server 13 accepts a CGI communication request from the communication proxy portion 34 of the computer 30, inquires data of the data collection portion 12, and transmits a result of the inquiry to the draw applet 32 in the computer 30.

In step c1 of FIG. 5C, the computer 30 performs the backup process to previously obtain various files in the storage portion 20 of the electronic apparatus 10, i.e., the HTML file 41, the applet file 42, and the communication proxy program in the communication proxy 43, in the format of FTP to the storage portion 40.

In step d1 of FIG. 5D, the computer 30 reads the HTML file 41 from the storage portion 40 to set the file as the draw applet 32.

In step d2 of FIG. 5D, the computer 30 reads the applet file 42 including the communication proxy program 43, from the storage portion 40, and sets the CGI communication applet 33 and the communication proxy portion 39.

In step d3 of FIG. 5D, the communication proxy program in the communication proxy portion 34 is activated to communicate with the data collection portion 12 in the electronic apparatus 10, thereby acquiring the data of the processes.

As a result of the series of processes, the computer 30 can previously obtain the HTML file 25, the applet 21, and the communication proxy program to the computer itself, and, in response to an operation on the browser 31 by the user, obtain the data of the processes, in CGI communication from the electronic apparatus 10.

Thereafter, the computer 30 can combine the display instructions from the draw applet 32 with the data from the communication proxy portion 34 to construct a web page, and display the web page to enable the statuses of various target processes to be monitored.

In this way, with using usual browser software (browser 31), the user of the computer 30 can monitor various data in a process which is processed by the electronic apparatus 10, such as an industrial process, a production line, and various experimental facilities, through the communication network L and in the display form of a web page.

In the third embodiment, the computer 30 previously obtains the HTML file 25 which functions as the base of drawing, the applet 24 including the CGI communication applet 33, and the communication proxy portion 26, from the electronic apparatus 10 in the backup process. In response to a subsequent operation on the browser 31, the computer obtains data of the processes by CGI communication.

In the backup process of the computer, displaying instructions for the HTML file 25 related to drawing, the applet related to displaying, and a communication proxy are transmitted. Thereafter, only various data are transmitted with the CGI. Consequently, high-speed processing is realized, and display instructions and data can be transmitted through the HTTP port at different timings. Therefore, it is not necessary to use a different dedicated socket (port: TCP/IP). Moreover, special setting for realizing communication is not required in a firewall of the network to which the electronic apparatus 10 and the computer 30 belong.

1. An electronic apparatus that reads an HTML file and an applet from a storage portion storing the HTML file and the applet, and transmits the HTML file and the applet to a computer through a communication network, comprising:
a data collection portion that collects data from an external process; and
a communication portion that transmits the HTML file and the applet read from the storage portion, and the data collected by the data collection portion to the computer through the communication network,
wherein the applet involves a CGI applet using CGI, which requests to transmit the data collected by the data collection portion.

2. The electronic apparatus according to claim 1,
wherein the communication portion transmits the HTML file, the applet and the data to the computer with using an identical port.

3. The electronic apparatus according to claim 1,
wherein the communication portion has a CGI communication portion that obtains data from the data collection portion in response to a request from the CGI applet.

4. An electronic apparatus system comprising an electronic apparatus and a computer which are connected through a communication network,
wherein the electronic apparatus comprises:
a data collection portion that collects data from an external process; and
a communication portion that transmits an applet read from a first storage portion storing an HTML file and the applet, and the data collected by the data collection portion to the computer,
the applet involves a CGI applet using CGI, which requests to transmit the data collected by the data collection portion, and
the computer comprises a second storage portion storing the HTML file stored in the first storage portion, and reads the HTML file from the second storage portion.

5. The electronic apparatus system according to claim 4,
wherein the computer performs a backup process in order to write the HTML file stored in the first storage portion into the second storage portion.

6. The electronic apparatus system according to claim 4,
wherein the communication portion transmits the applet and the data to the computer with using an identical port.

7. The electronic apparatus system according to claim 4,
wherein the first storage portion stores a communication proxy in order to communicate between the computer and the electronic apparatus,
the second storage portion stores the applet stored in the first storage portion and the communication proxy, and
the computer reads the HTML file, the applet and the communication proxy from the second storage portion.

8. The electronic apparatus system according to claim 7,
wherein the computer performs a backup process in order to write the HTML file, the applet and the communication proxy stored in the first storage portion into the second storage portion.
